(19) United States
(12) Patent Application Publication
(10) Pub. No.: US 2008/0164465 A1
(43) Pub. Date: Jul. 10, 2008

(54) Electronic Device

(75) Inventors: Albert Jose Jan Marie Van Breemen, Eindhoven (NL); Peter Tobias Herwig, Eindhoven (NL); Jorgen Sweelssen, Eindhoven (NL); Caecilia Hendrina Theodora Chlon, Eindhoven (NL); Harmannus Franciscus Maria Schoo, Eersel (NL); Dago De Leeuw, Eindhoven (NL); Sepas Setayesh, Eindhoven (NL); Wilhelmina Maria Hardeman, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/816,301

(22) PCT Filed: Feb. 15, 2006
(86) PCT No.: PCT/IB2006/050498

§ 371 Date: Aug. 15, 2007

(30) Foreign Application Priority Data
Feb. 18, 2005 (EP) 05101249.0

(51) Int. Cl. H01L 51/30; H01L 51/40; C08G 75/00

(52) U.S. Cl. 257/40; 438/99; 528/380; 257/E51.027

(57) ABSTRACT

The electronic device comprises an organic semiconductor material in a monodomain structure on a substrate. Said semiconductor material is preferably part of a transistor, wherein the monodomain extends on the channel, i.e. from a source to a drain electrode. The material comprises a mesogenic unit with spacer groups and end groups. The end groups are preferably reactive, i.e. dienes, acrylates, oxetanes or the like. The mesogenic unit contains a central oligothiophenyl-group, rigid spacer groups, particularly acetylenes, and additional groups, for instance thiophenyl or phenyl.

The invention relates to an electronic device comprising a semiconductor element provided with an organic semiconductor material that comprises one or more mesogenic units having a structure of E¹-D¹-A¹-Z¹-A²-Z²-A³-D²-E², in which structure E¹, E² are end groups, D¹, D² are spacer groups, A¹, A², A³ are optionally substituted conjugated units and Z¹, Z² are rigid spacer groups.

The invention also relates to a method of manufacturing device, and to a reactive mesogenic compound. The invention further relates to an electronic device comprising a thin-film transistor provided with a source electrode and a drain electrode that are mutually separated by a channel containing an organic semiconductor material comprising one or more reactive mesogenic units, which transistor is further provided with a gate electrode that is separated from the channel by a gate dielectric.

Such an electronic device is known from WO-A 03/006468. This patent application discloses, in its first example, a material having a fused thiophene-system, i.e. a dithienothiophenyl-group, as conjugated group A². The rigid spacer groups are acetylene groups. The conjugated groups A¹, A³ are phenyl groups. The linear spacer groups are aliphatic alcoholic groups, i.e. —O—C₃H₆—. The end groups are acrylates, i.e. —OC(O)CH═CH₂, which is polymerisable. The material has phase transitions between its crystalline, smectic and nematic phases.

These types of materials are known as reactive mesogenes and can be aligned after deposition. This will result in a lamellar structure of the organic semiconductor material. After provision of the orientation in the smectic phase, polymerisation can take place so as to maintain the desired form of this molecular system. It has been found, as is explained in the article J. Mater. Chem. 13 (2003), 2436-2444 of the same group of inventors, that the alignment promotes the formation of large area domains in the organic semiconductor material. Such large area domains persisting throughout the area of the alignment layer are also called monodomains. As grain or phase boundaries generally cause charge trapping in organic semiconductors, the formation of monodomains is advantageous in optimizing charge carrier mobilities.

It is however a disadvantage that alignment of the materials disclosed in the patent application is difficult or at least not easy. The material of the first example has its crystalline-smectic phase transition at 120° C., its smectic-nematic phase transition at 145° C. and its nematic-isotropic phase transition at 167° C. The conversion of such a material to the highly ordered smectic or crystalline phase is generally accomplished by slowly cooling from the isotropic phase. In view of the relatively high transition temperatures, the material is believed to quickly enter into the highly ordered smectic phase, and thus become more viscous. This viscoelastic behavior hampers alignment. It would thus be desirable to have materials with a larger temperature difference between the mentioned phase transitions.

It is therefore a first object of the invention to provide a device of the kind mentioned in the opening paragraph having an organic semiconductor material that can be properly aligned.

In a first aspect of the invention, this is achieved in that the conjugated group A² comprises an oligothiophenyl group. Surprisingly, the use of mesogenic units with an oligothiophenyl group has been found to lead to improved processability, good temperature stability and formation of monodomain structures.

In a second aspect of the invention, this is achieved by means of a method, as claimed in claim 7, comprising an alignment step.

The term ‘monodomain structure’ is understood, in the context of the invention, to be an ordered structure substantially without internal grain or phase boundaries, which is of sufficient size for continuous transport of charge carriers. Particularly, it is as large as a channel in a transistor, extending from a first to a second electrode. In the context of the invention, this applies particularly to monodomains in one of the smectic phases and crystalline phases. These phases are most ordered, which leads to the highest mobility in the resulting organic semiconductor material.

In comparison with the prior art, the fused thiophene ring system has been replaced with a oligothiophene unit. This has resulted in the surprisingly improved behavior. One explanation for the results is that an oligothiophene is a less rigid unit than a fused ring system, although both are planar. This appears to be an important aspect for the stress in the oriented structure: only if the inherent stress is limited over a large area, the monodomain structure can be formed and be stable, also after photopolymerisation.

It is observed that the article referred to discloses other materials with a mesogenic unit of another structure. Instead of -A¹-Z¹-A²-Z²-A³-, the mesogenic unit is phenyl naphtalene in a first example and quaterthiophene in a second example. It is however observed that the materials containing the thiophene groups could not be aligned properly, and multidomain, poorly aligned semiconductor films were obtained. This was attributed to the large increase in viscosity on immediately entering the high order smectic phases that formed from the isotropic phase.

It is furthermore acknowledged that a mesogenic unit as present in the organic semiconductor material is known per se from Zhang et al, Synt. Metals 126 (2002), 11-18. However, the conclusion of the article is that insertion of a triple bond between thiophenes is unfavorable for π-delocalization. The molecular structure is asymmetric in the crystalline form. The two terminal thiophenes are not coplanar with the three central ones. This shortens the conjugation length considerably. As such, the compound appears not very suitable for use in semiconductor elements, and this use is not disclosed. However, by formation of the monodomain structure, the conjugated units A² of different molecules are adjacent to each other and form a major path for charge transport. The fact that the acetylene group reduces charge transport between the conjugated units A¹, A³ and A², does not matter very much. In fact, the dihedral angle may well contribute to the formation of monodomains, in that the non-planar structure is repeated easily in adjacent mesogenic units.

The applied mesogenic units preferably have a nematic phase. Although the nematic phase generally is not the ordered phase, in which the mesogenic units are photopolymerized, it was observed that the presence of a nematic phase is advantageous for obtaining a well-ordered smectic phase or even crystalline phase. Moreover, it was found to reduce defects and the number of grain boundaries. Suitably, the transition from the isotropic to the nematic phase occurs at a relatively low temperature, which is for instance in the range of 120-200° C., more particularly between 140 and 160° C. Most preferably, the applied mesogenic units additionally have more than one smectic phase.

The oligothiophenyl group suitably comprises a chain of two, three, four, five or six thiophene groups. Preferably, the chain length is two, three or four. Optionally, the conjugated group A² may contain further conjugated elements such as a 1,4-phenylene group, a phenylene-vinylene group, a thienylene-vinylene group, a furanylene group, a furanylene-vinylene group, an aniline group, a pyrrhol group, a dicyclopentaterthiophendione. This is not preferred, however. Any of the A2 groups may be substituted with side groups known in the art. Suitable side groups are for instance alkyl, alkoxy, perfluoroalkyl, alkylcarbonyl, alkylcarbonyloxo, perfluoroalkylcarbonyl and perfluoroalkylcarbonyloxo side groups. The lower alkyls, alkoxys perfluoroalkyls, alkylcarbonyls, alkylcarbonyloxos, perfluoroalkylcarbonyls and perfluoroalkylcarbonyloxo are preferred herein in order not to counteract the formation of an ordered structure.

Suitable side groups preferably have a length of between 1 and 20 carbon atoms, more preferably from 4 to 10 carbon atoms and most preferably from 6 to 8 carbon atoms. Particularly good results have been obtained with a symmetrically built-up compound. In that case the conjugated units A¹ and A³ are the same. Examples of conjugated units A¹ and A³ are for instance thiophenylene, thienylene vinylene, furanylene, furanylene vinylene, phenylene, pyrrolene, oligothiophenyl, with 2 to 4 thiophenylgroups, which groups may be optionally substituted. The intermediate rigid spacer groups Z¹, Z² are preferably acetylene groups, but may alternatively be —CH═CH—, —CH═CH—CH═CH—, —N═N—, —CH═N—, —N═CH—, —O—, —S—, OCH₂—, —CH₂O—, —SCH₂—, CH₂S—, —CF₂O—, —OCF₂—, CF₂S—, —SCF₂, —CH₂—CH₂—, —CF₂CH₂—, CH₂CF₂—, —CF₂CF₂—, CH═CR⁰, with R⁰ being alkyl with 1 to 12 C-atoms.

In a most suitable embodiment, at least part of the end groups are reactive end groups of which at least part is cross-linked into a polymer network. Cross-linked monodomains have not been disclosed by either the patent application or the articles referred to. The patent discloses the synthesis of several compounds, as well as phase behavior and transition temperatures of these compounds. However, none of the examples discloses the photopolymerisation. The article mentions an increase in mobility after a thermal treatment when samples are slowly cooled from the isotropic to the smectic phase, where much larger and better ordered domains are formed. Nevertheless, the reactive mesogens that are photopolymerized are stated to be multidomain, poorly aligned semiconductor films, as is stated on page 2443, 2^{nd} column of the article. Moreover, upon photopolymerisation, a five-fold reduction in mobility was found, which is explained by a reduced degree of molecular order.

With the mesogenic unit of the invention, cross-linked monodomains have been obtained.

The reactive end groups in the organic semiconductor material preferably may react to form at least two bonds per reactive end group. Such bonding of the end groups leads to a relatively strong network that is sufficiently strong to withstand vibrations of the molecules at increased temperature.

Moreover, it is highly preferred that the distance between the end groups of different molecules is comparable to the distance between the mesogenic units. This provides a good structure, leading to a minimum of stress within the material.

Surprisingly, it has turned out that better monodomain structures are obtained when different mesogenic units are present, provided that the mesogenic units are in the same phase. The monodomain structures obtained with such mixtures show a highly planar surface. This is very important in order to obtain good quality transistors, as the interface between semiconductor and dielectric material is of primary importance in the operation of the transistor. It is in this region of the semiconductor material that, under the influence of the application of a gate voltage, depletion or accumulation of charge carriers occurs.

Preferably, the organic semiconductor material comprises different mesogenic units, said units differing in the spacer groups. Particularly the spacer group of a first mesogenic unit has a longer chain length than the spacer group of a second mesogenic unit (D1 and D2). In one advantageous embodiment, the chain length in the first unit is six and that in the second unit is ten.

If the mesogenic units applied in the semiconductor material comprise mutually different conjugated units, then it is highly preferred that the energy levels of these conjugated units, which are relevant for the semiconductor behavior, are similar or the same. The relevant energy level for p-type conduction is the highest occupied molecular orbital (HOMO) and for n-type conduction is the lowest unoccupied molecular orbital (LUMO). The distance between the HOMO and the LUMO level is known as the band gap. Similarity of the HOMO and LUMO levels for the p- and n-type conduction between the conjugated units in different molecules is required in order to reduce the barrier against charge carrier transport between the molecules. This type of charge carrier transport is crucial for the semiconductor behavior.

The presence of the unit in the organic semiconductor material is understood to cover both the situation in which the mesogenic unit is present as a monomer and the situation in which it is included in a polymeric network. Such a network comes into being upon photopolymerisation of the reactive end groups. Such a network is for instance known from WO-A 2003/79400, that is included herein by reference. It is not excluded that, in addition to the mesogenic units, further monomers are present to create another type of network. Although the embodiment in which the organic semiconductor material is present as monomers is not preferred for the operating transistor, it is not excluded that this is an advantageous semi-manufactured article.

Although it appears advantageous that all mesogenic units in the organic semiconductor material have two reactive end groups E¹, E², it may well be that a portion of the materials has only one reactive end group. It is even possible that some of the mesogenic units do not have a reactive end group at all. Alternatively, some or all of the mesogenic units may have more than two reactive end groups. In fact, the number of end groups needs to be such that there are sufficient cross-links available for maintenance of the ordered monodomain structure on temperature increase or on exposure to a solvent for the individual mesogenic units.

Suitable spacer groups D¹, D² are linear. The spacer groups are preferably of the general formula S—X. Herein S is an alkylene group with up to 20 C atoms which may be unsubstituted, mono- or polysubstituted by F, Cl, Br, I or CN, it also being possible for one or more non-adjacent CH₂-groups to be replaced, in each case independently of one another, by —O—, —S—, —NH—, —NR—, —SiR⁰R⁰⁰—, —CO—, —COO, —OCO—O—, OCO—, —SCO—, —CO—S—, —CH═CH— or —C≡C—, in such a manner that O and/or S atoms are not linked directly to one another. In said general formula, X is —O—, —S—, —CO—, —COO—, —OCO—, —OCO—O—, —CO—NR⁰—, NR⁰—CO—, OCH₂—, —CH₂O—, —SCH₂—, —CH₂S—, CF₂O—, OCF₂—, —CF₂S—, —SCF₂—, —CF₂CH₂—, —CH₂CF₂—, —CF₂CF₂—, —CH₂CH₂, —CH₃, —S(CF₂)ₙCF₃, —S(CH₂)ₙCH₃, —(CF₂)ₙ(CH₂)ₘCH₃, —(CH₂)ₙ(CF₂)ₘCF₃, —(CF₂)ₙCF₃, —(CH₂)ₙCH₃, —CH═N—, —N═CH—, —N═N—, —CH═CR⁰, —CX¹αCX², —C≡C—, —CH═CH—COO—, —OCO—CH═CH— or a single bond, and X¹, X² has the same meaning as X and R⁰ and R⁰⁰ are, independently of each other H or alkyl with 1 to 12 C-atoms. N and m are, independently of each other, between 1 and 20.

Preferably, the spacer group has a chain length of at least six atoms and at most ten atoms, and most preferably, the alkylene group S has a chain length of at least six atoms. It has been found that this is suitable to maintain the monodomain structure during photopolymerisation. The use of shorter spacer groups tends to lead to mutual rotation of neighboring mesogenic units in the monodomain structure, and hence loss of order.

Suitable end groups E¹, E² are for instance CH₂═CW¹—COO—, epoxides, oxetanes, CH²═CW²—(O)ₖ₁—, CH₃—CH═CH—O—, HO—CW²W³—, HS—CW²W³—, HW²N—, HO—CW²W³—NH—, CH₂═CW¹—CO—NH—, CH₂═CH—(COO)ₖ₁-Phe-(O)ₖ₂—, Phe-CH═CH—, HOOC—, OCN— and W⁴W⁵W⁶Si—, with W¹ being H, Cl, CN, phenyl or alkyl with 1 to 5 C atoms, in particular H, Cl or CH₃, W² and W³ being, independently of each other, H or alkyl with 1 to 5 C atoms, in particular methyl, ethyl or n-propyl, W⁴, W⁵ and W⁶ being, independently of each other, Cl, oxaalkyl, oxacarbonylalkyl with 1 to 5 C-atoms, Phe being 1- or 1,2- or 1,3-, 1,4-phenylene and k₁ and k₂ being, independently of each other, 0 or 1. Particularly preferred are oxetane, acrylate, methacrylate, amide, diene and oxetal groups.

Most preferred end groups are oxetane and acrylate groups.

The reaction of the reactive groups with each other to form a network can be initiated by irradiation with radiation of a suitable wavelength. Examples of suitable kinds of radiation include UV light, IR light or visible light, X-rays, gamma-rays, laser light and even high energy particles. A photochemical initiator is present to start the reaction. Various initiators known in the art may be used, which are either radical photoinitiators or cationic photoinitiators, in dependence on the type of end group used.

After cross-linking, the non-cross-linked part of the organic semiconductor layer may be removed in a suitable solvent, such as for instance acetone. This allows patterning of the layer into a desired pattern. In one embodiment, selected areas of the layer are removed, so as to create vertical interconnect areas. In another embodiment, the organic semiconductor layer is substantially removed and maintained particularly in those areas in which it fulfills an electrical function. As the monodomain is in an ordered phase, particularly below the glass temperature, removal of a major part of the semiconductor layer is suitable in view of the mechanical properties. Particularly, mechanical stability under bending may be improved.

In one further embodiment, a second organic semiconductor layer is provided in an area next to the—first—patterned organic semiconductor layer. This allows the provision of a circuit with devices having different semiconductor layers. Hence, devices with different properties may be provided on one substrate adjacent to each other.

In another further embodiment, an electrically insulating layer is provided on top of the semiconductor layer, such that it encapsulates the semiconductor layer. The insulating layer might work as the dielectric in a field-effect transistor. As stated in WO 03/052841 A1.

In a further modification, use is made of a single alignment layer that is separate from the interface between the channel and the gate dielectric. This is particularly achievable with a top gate structure of the transistor. A particularly preferred alignment layer is rubbed polyimide. Typically, this has a thickness of about 50 nm. When this is used in a conventional bottom gate structure, the polyimide layer will be present on the gate dielectric. This countereffects tremendously the properties of the transistor, for which the interface between the gate dielectric and the channel is of primary importance. The article in J. Mater. Chem. 13 (2003), 2436-2444, as mentioned above, suggests the use of hexamethyldisilazane (HMDS) as an alignment layer. This is generally not much more than a monolayer and hence its effect on the transistor properties is considered to be limited. However, such a layer is not sufficiently effective to obtain alignment over a large area such as needed to obtain a monodomain structure. Moreover, the use of hexamethyldisilazane is particularly useful in combination with a silicon oxide gate dielectric. This inorganic dielectric is not preferred for industrial application of thin film transistors. Another disadvantage of the HMDS-treated surfaces is their low polarity and therefore the high dewetting potential for the small-molecule organic semiconductors through annealing.

The orientation of the mesogenic units is conventionally carried out with an alignment layer. Although the alignment layer preferably has an interface with the organic semiconductor layer, other embodiments are not excluded. For instance, the alignment layer may be integrated in the substrate. Alternatively, the alignment layer and the substrate could be removed after manufacture of the device. Substrate transfer techniques are known per se in the art. The orientation layer can be provided on a portion of the substrate only. To his end, a photolithographically patternable orientation layer may be used. Alternatively, other alignment techniques may be used, in which semiconductor material is oriented by alignment of additives in the material by means of a source located at a distance. It would be possible to use, for instance, the magnetic field for alignment, or add surface-active compounds to the material.

It has been found suitable that the organic semiconductor layer has a limited thickness only, particularly below 100 nm. At a larger thickness of the organic semiconductor layer, the formation of multidomains tends to be favored over the formation of monodomains, with a corresponding decrease in mobility. If a larger thickness is desired, a second organic semiconductor layer may be provided on top of the first semiconductor layer, after stabilizing the desired phase and orientation of the first layer stabilized by cross-linking.

Most suitably, the transistor is made in a so-called top gate geometry. This means that the gate electrode is deposited only after the provision of a gate dielectric on top of the semiconductor layer. This has the advantage of greater freedom in the choice of the gate dielectric, as it does not need to fulfill the function of alignment layer simultaneously.

In a further modification, the gate dielectric comprises a material with a low permittivity, particularly between 1 and 3, such as porous materials, and polyalkylenes and polyarylenes. Examples of such materials are for instance poly (p-xylylene), polyethylene, polypropylene, polyisoprene and polystyrene. Most preferably, the gate dielectric comprises a further insulator layer that has a higher permittivity than the low permittivity material. As stated in WO 03/052841 A1.

The invention further relates to compounds for use in the invention that are cross-linkable. These are the reactive mesogenic units as explained above, with at least one reactive end group. Reactive end groups are considered advantageous in comparison to end groups elsewhere, in that they tend to minimize deterioration of the aligned and oriented structure.

The invention also relates to polymers formed from these compounds in the cross-linking process. Such polymers are particularly formed after deposition on a substrate.

The invention further relates to a semi-manufactured article. Alignment of liquid crystalline materials can be achieved in many different ways known in the art. It is thus foreseen that substrates with aligned and cross-linked layers of the polymer of the invention will be sold as a unit.

The invention also relates to a composition comprising two different reactive mesogenic monomers. As explained above, very good results have been achieved with mixtures resulting particularly in that the top surface of the semiconductor layer is highly planar. This improves the interface behavior, and is particularly important for transistor performance, as is explained above. This aspect of the use of different reactive mesogenic monomers to provide improved monodomains is valid also for reactive mesogenic monomers other than those of the invention.

These and other aspects of the invention will be further explained with reference to the Figures, in which:

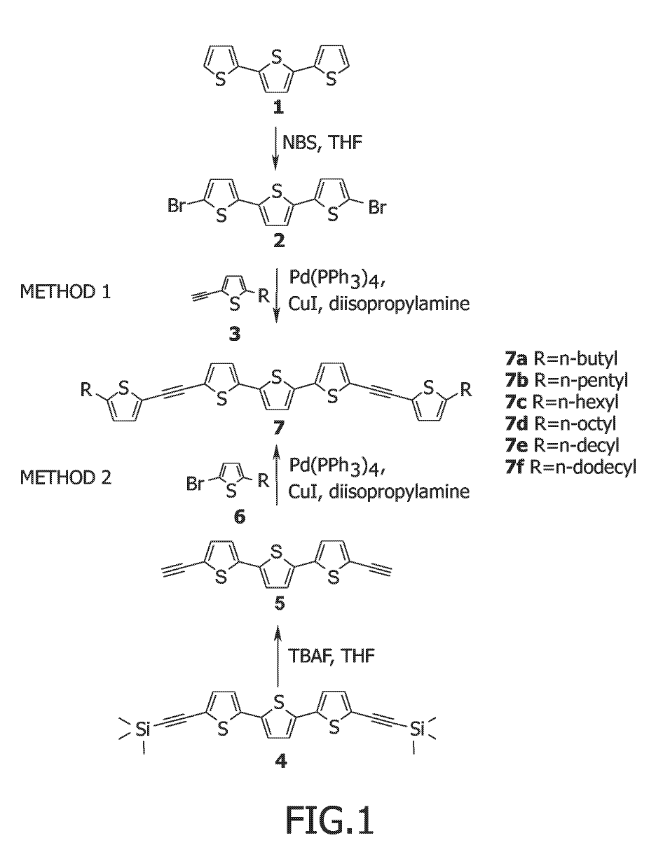

FIG. 1 is a reaction scheme for the preparation of the mesogenic units;

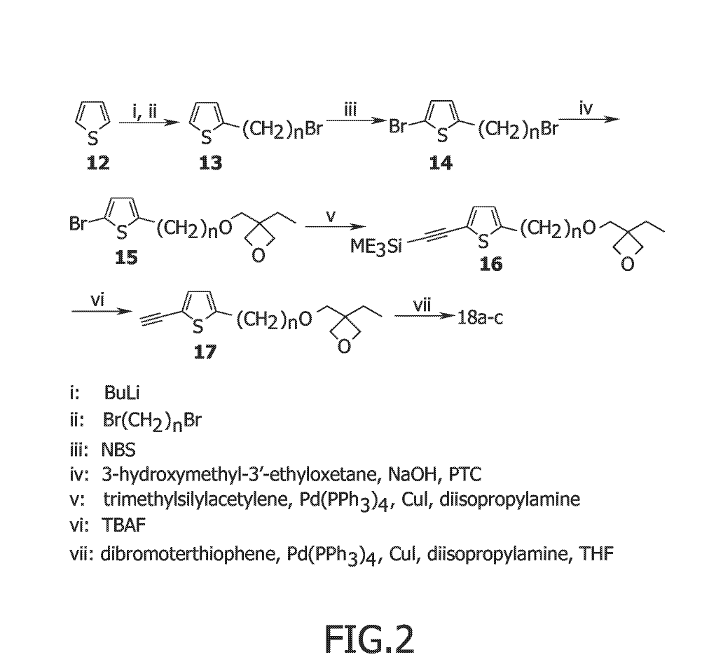

FIG. 2 is a reaction scheme for the preparation of the mesogenic units of FIG. 1 with oxetane reactive end groups;

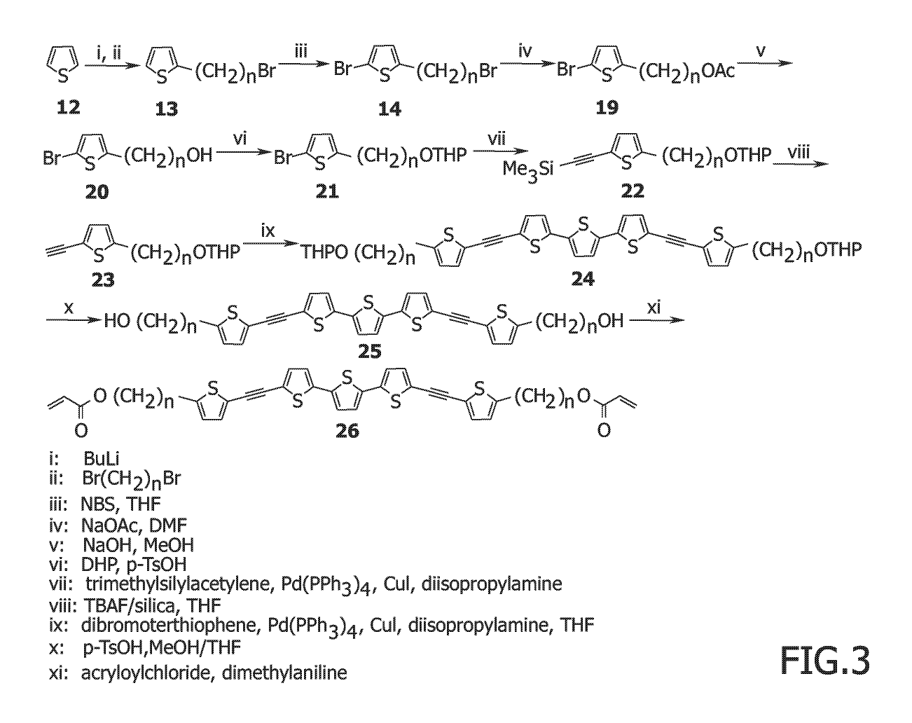

FIG. 3 is a reaction scheme for the preparation of the mesogenic units of FIG. 1 with acrylate reactive end groups;

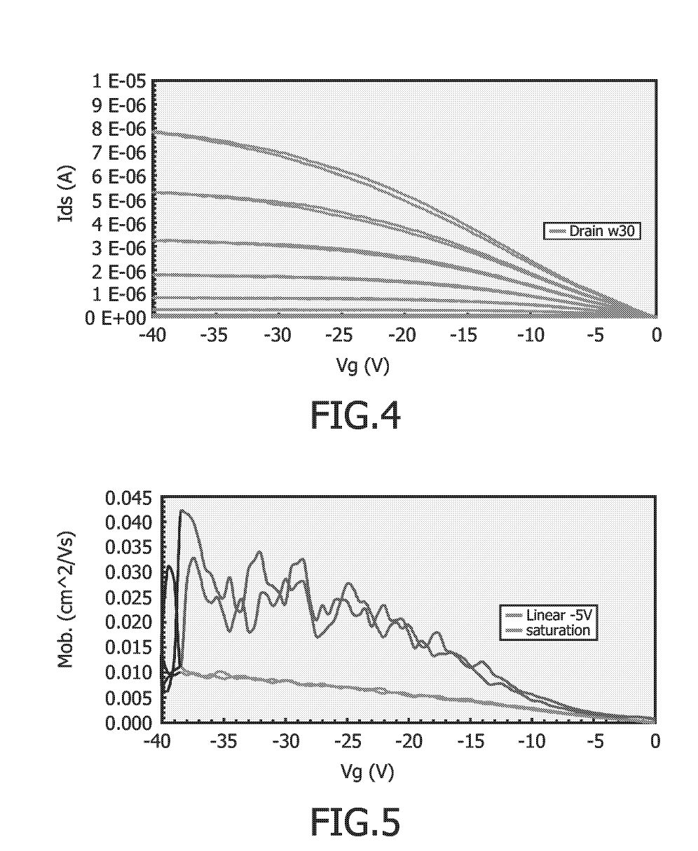

FIG. 4 is a graph showing the output characteristics of the transistor having a top gate geometry and comprising the mesogenic units of FIG. 1 as semiconductor material;

FIG. 5 is a graph of the linear and saturated mobility as a function of gate bias, relating to the same transistor as that in FIG. 4.

### EXAMPLES

The following LC semiconductors were prepared and characterized:

(a) 5,5″-bis(5-alkyl-2-thienylethynyl)-2,2′:5′,2″-terthiophenes;

(b) 5,5″-bis(4-alkyl-1-phenylethynyl)-2,2′:5′,2″-terthiophenes;

(c) 5,5″-bis(5-alkyl-2-thienylethynyl)-2,2′-bithiophenes

(d) 5,5″-bis(4-alkyl-1-phenylethynyl)-2,2′-bithiophenes

(e) 5,5″-bis(5-(oxetane-alkyl)-2-thienylethynyl)-2,2′:5′,2″-terthiophenes;

(f) 5,5″-bis(5-(acrylate-alkyl)-2-thienylethynyl)-2,2′:5′,2″-terthiophenes;

Examples a-d are mesogenes without reactive end groups, examples e,f relate to mesogenic units with reactive end groups.

### Synthesis

FIG. 1 shows two different synthesis methods for the preparation of a series of LC semiconductors based on bis(2-thienylethynyl)-2,2′:5′,2″-terthiophene 7. Method 1 is known from Zhang et al, Synt. Metals 126 (2002), 11-18. Both methods include a Sonogashira coupling of a bromo-(oligo)thiophenyl with an ethynyl-substituted (oligo)thiophenyl. Method 2 has a couple of disadvantages: the reagent diethynyl-terthiophene used in method 2 is not stable; the Sonogashira coupling in prior art method 2 has a low yield (<20%) and is not reproducible. Contrarily, the Sonogashira coupling in method 1 gives reproducible yields of about 80%. Method 1 can be used for the preparation of any of the above mentioned compounds.

FIG. 2 shows a synthetic route for the preparation of reactive mesogenic units, wherein the reactive end group is an oxetane group.

FIG. 3 shows a synthetic route for the preparation of reactive mesogenic units, wherein the reactive end group is an acrylate group.

### Synthesis of 5,5″-bis(5-alkyl-2-thienylethynyl)-2,2′:5′,2″-terthiophenes

### Example 1

### Preparation of 2-alkyl-5-trimethylsilylethynyl Thiophenes

To a degassed solution of 2-bromo-5-alkyl thiophene (40 mmol) and diisopropylamine (50 mL), there was added Pd(PPh₃)₄ (3 mol %). The mixture was again degassed and heated for 15 minutes at 40° C. Trimethylsilylacetylene (60 mmol) and CuI (3.5 mol %) were subsequently added and the mixture was stirred for 18 hours at 85° C. After cooling to room temperature, the mixture was diluted with CH₂Cl₂, filtered over Celite and concentrated in vacuo. The crude product was purified by column chromatography.

### Example 2

### Preparation of 5,5″-bis(5-alkyl-2-thienylethynyl)-2,2′:5′,2″-terthiophenes 7

To a mixture of 2-alkyl-5-trimethylsilylethynyl thiophene (19 mmol) in dry THF (50 mL), TBAF on silica (21.6 g, 24 mmol) was added under N₂. After 5 minutes the mixture was filtered over Celite and concentrated in vacuo. This material was immediately used in the next step.

To a degassed solution of dibromoterthiophene (3.05 g, 7.5 mmol) and 2-alkyl-5-ethynyl thiophene 3 (19 mmol) in diisopropyamine (60 mL) and THF (15 mL), Pd(PPh₃)₄ (260 mg, 0.22 mmol) is added. The mixture is again degassed and heated for 15 minutes at 40° C. Subsequently, CuI (100 mg, 0.52 mmol) is added and the mixture is heated at reflux for 18 hours. The solution was allowed to cool to room temperature, CH₂Cl₂ (100 mL) was added and the precipitate was filtered off over Celite. The filtrate was concentrated in vacuo, purified by column chromatography on silica using hexane-CH₂Cl₂followed by recrystallization from hexane.

### Synthesis of Reactive Mesogenic Units with Oxetane End Groups

### Example 3

### Preparation of 3-[ω-(5-bromothiophen-2-yl)-alkyloxymethyl]-3-ethyl-oxetanes 15

A mixture of 2-bromo-5-(ω-bromoalkyl)thiophene (46 mmol), 3-hydroxymethyl-3-ethyloxetane (60 mmol), n-Bu₄Br (5 mol %), hexane (50 mL) and aqueous NaOH (50 wt. %, 50 mL) was stirred for 18 hours at 80° C. After cooling to room temperature, the mixture was extracted with hexane and washed with water (3×150 mL). The crude product was purified by column chromatography.

### Example 4

### Preparation of 3-[ω-(5-trimethylsilylethynyl-thiophen-2-yl)-alkyloxymethyl]-3-ethyl-oxetanes 16

To a degassed solution of 3-[ω-(5-bromothiophen-2-yl)-alkyloxymethyl]-3-ethyl-oxetane (40 mmol), and diisopropylamine (50 mL), Pd(PPh₃)₄ (3 mol %) was added. The mixture was again degassed and heated for 15 minutes at 40° C. Trimethylsilylacetylene (60 mmol) and CuI (3.5 mol %) were subsequently added and the mixture was stirred for 18 hours at 85° C. After cooling to room temperature, the mixture was diluted with CH₂Cl₂, filtered over Celite and concentrated in vacuo. The crude product was purified by column chromatography.

### Example 5

### Preparation of bisoxetanes 18

To a mixture of 3-[ω-(5-trimethylsilylethynyl-thiophen-2-yl)-alkyloxymethyl]-3-ethyl-oxetanes (19 mmol) in dry THF (50 mL), TBAF on silica (21.6 g, 24 mmol) was added under N₂. After 5 minutes the mixture was filtered over Celite and concentrated in vacuo. This material was immediately used in the next step.

To a degassed solution of dibromoterthiophene (3.05 g, 7.5 mmol) and 3-[ω-(5-ethynyl-thiophen-2-yl)-alkyloxymethyl]-3-ethyl-oxetanes 17 (19 mmol) in diisopropyamine (60 mL) and THF (15 mL), there is added Pd(PPh₃)₄ (260 mg, 0.22 mmol). The mixture is again degassed and heated for 15 minutes at 40° C. Subsequently, CuI (100 mg, 0.52 mmol) is added and the mixture is heated at reflux for 18 hours. The solution was allowed to cool to room temperature, CH₂Cl₂ (100 mL) was added and the precipitate was filtered off over Celite. The filtrate was concentrated in vacuo, and purified by column chromatography on aluminum oxide using hexane ethylacetate.

### Synthesis of Reactive Mesogenic Units with Acrylate End Groups

### Example 6

### Preparation of bisTHP ethers 24

To a mixture of 2-[ω-(5-trimethylsilylethynyl-thiophen-2-yl)-alkoxy]-tetrahydropyran 22 (19 mmol) in dry THF (50 mL), TBAF on silica (21.6 g, 24 mmol) was added under N₂. After 5 minutes the mixture was filtered over Celite and concentrated in vacuo. This material was immediately used in the next step.

To a degassed solution of dibromoterthiophene (3.05 g, 7.5 mmol) and 2-[ω-(5-ethynyl-thiophen-2-yl)-alkoxy]-tetrahydropyran 17 (19 mmol) in diisopropyamine (60 mL) and THF (15 mL), there is added Pd(PPh₃)₄ (260 mg, 0.22 mmol). The mixture is again degassed and heated for 15 minutes at 40° C. Subsequently, CuI (100 mg, 0.52 mmol) is added and the mixture is heated at reflux for 18 hours. The solution was allowed to cool to room temperature, CH₂Cl₂ (100 mL) was added and the precipitate was filtered off over Celite. The filtrate was concentrated in vacuo, and purified by column chromatography on aluminum oxide using hexane CH₂Cl₂.

### Example 7

### Preparation of bishydroxies 25

A solution of bis-THP ether 24 (5.3 mmol) and p-toluene sulfonic acid (2.6 mmol) in a mixture of MeOH (200 g) and THF (90 g) was degassed and subsequently heated to reflux for 30 minutes. The hot (50° C.) solution was precipitated in water. The solid was filtrated, washed with water and dissolved in THF. This solution was dried over MgSO₄ and concentrated in vacuo.

### Example 8

### Preparation of bisacrylates 26

A heterogeneous mixture of hydroxy compound 25 (4.8 mmol) and dimethylaniline (14.5 mmol) in dichloromethane (120 mL) is cooled to 0° C. Acryloylchloride (14.5 mmol) is added. After 18 hours of stirring at room temperature again dimethylaniline (4 mmol) and acryloylchloride (4 mmol) and a catalytic amount of dimethylaminopyridine is added. After 40 hours at room temperature, the homogeneous solution is washed with water (75 mL), aqueous HCl (0.5 M, 75 mL), and again water (4×75 mL). The combined organic fractions were dried over MgSO₄ and concentrated in vacuo. The crude product was dissolved in dichloromethane, filtered over Al₂O₃ and purified by precipitation.

### Characterization of Phase Behavior of 5,5″-bis(5-alkyl-2-thienylethynyl)-2,2′:5′,2′-terthiophenes

Six derivatives 7a-f, differing in spacer length, were synthesized. The phase behavior was examined using a combination of DSC, polarization microscopy and X-ray measurements. Preliminary results are depicted in Table 1.

TABLE 1
phase behavior of 7a-f

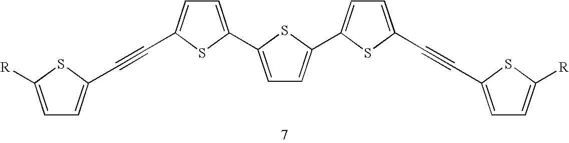

R

| | | | | | | | | | |
|---|---|---|---|---|---|---|---|---|---|
| 7a n-butyl | Cr | 54 | S_{B} | 90 | | | N | 191 | I |
| 7b n-pentyl | | | | | | | | | |
| 7c n-hexyl | | 39 | | 64 | | 107 | N | 162 | I |
| 7d n-octyl | | 18 | | 75 | 111 | 134 | | 157 | I |
| 7e n-decyl | | 52 | | 75 | 107 | 141 | | 148 | I |
| 7f n-dodecyl | | | | 90 | 108 | | | 142 | I |

### Characterization of Phase Behavior of 5,5″-bis(4-alkyl-1-phenylethynyl)-2,2′:5′,2′-terthiophenes

The phase behavior of the phenyl analogs of compound 7 is depicted in Table 2. These were prepared according to method 1, with this difference, that a commercially available 1-alkyl-4-ethynylbenzene is used

TABLE 2
phase behavior of 9a-c

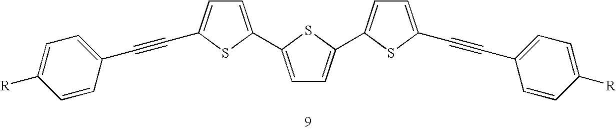

R

| | | | | | | |
|---|---|---|---|---|---|---|
| n-C₄H₉ | | 123 | 177 | N | | |
| n-C₆H₁₃ | | 73 | 182 | N | 200 | I |
| O-n-C₆H₁₃ | −26 | 65 | 182 | N | 206 | I |

### Characterization of the Phase Behavior of 5,5″-bis(5-alkyl-2-thienylethynyl)-2,2′-bithiophenes and 5,5″-bis(4-alkyl-1-phenylethynyl)-2,2′-bithiophenes

Two derivatives 10 and 11 were synthesized, in which the central terthiophene unit was replaced by a bithiophene unit. The synthesis is analogous to that of derivatives 7. Instead of dibromoterthiophene, dibromobithiophene is used in the Sonogashira coupling. The phase behavior of 10 and 11 is depicted in Table 3.

TABLE 3
phase behavior of 10-11

| | | | |
|---|---|---|---|
| 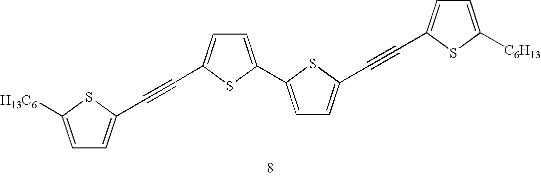 | 30 | 70 | 72 |
| 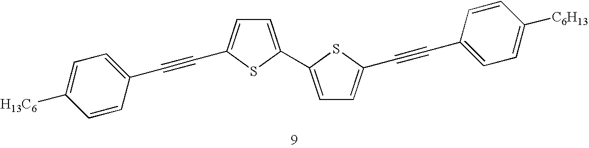 | 123 | 189 | |

### Characterization of the Phase Behavior of 5,5″-bis(5-(oxetane-alkyl)-2-thienylethynyl)-2,2′:5′,2″-terthiophenes

The phase behavior of the bisoxetanes is depicted in Table 8.

TABLE 4
phase behavior of 18

| 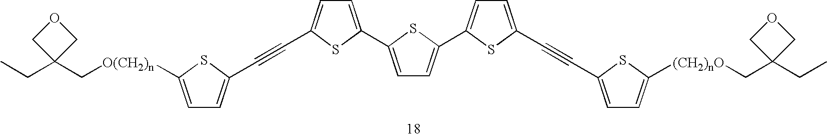 | | | |
|---|---|---|---|
| N | | | |
| 4 | 54 | | |
| 6 | 54 | 69 | 71 |
| 8 | 51 | 68 | 85 |

### Characterization of the Phase Behavior of 5,5″-bis(5-(acrylate-alkyl)-2-thienylethynyl)-2,2′:5′,2″-terthiophenes

The phase behavior of the bisacrylates is depicted in Table 10.

TABLE 5
phase behavior of 26

| 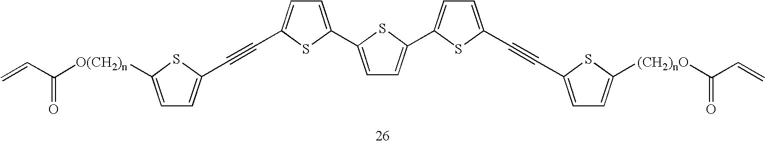 | | | | |
|---|---|---|---|---|
| n | | | | |
| 6 | 25 | 53 | 106 | 140 |
| 8 | | | | |

### Mobility

The mobility of the prepared LC materials was characterized by application of these materials on standard hexamethyldisilazane (HMDS)-primed SiO₂ test substrates. These test substrates include a field effect transistor set up without a semiconductor material. The device geometry is that of a bottom gate. Here, the gate is a highly doped area in the silicon substrate. Source and drain electrodes of gold are present on top of the SiO₂ layer.

Experiments were carried out at 40° C. in air/light and at 100° C. using the time of flight (TOF) technique, as known per se to the skilled person. Results are given in Table 2

TABLE 2
field-effect mobilities of 7a-f on standard
HMDS-primed SiO₂ bottom gate test devices

| | μ | μ |
|---|---|---|
| | (cm²/Vs) | (cm²/Vs) |
| | 40° C. | 100° C. |
| 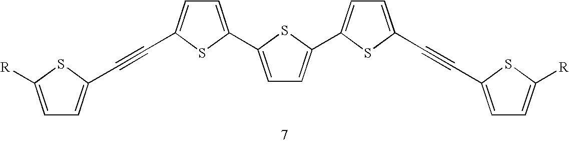 | | |
| 7a R = n-butyl | 1.0 * 10⁻⁴ | |
| 7b R = n-pentyl | 1.0 * 10⁻⁴ | 1.9 * 10⁻² |
| 7c R = n-hexyl | 2.0 * 10⁻³ | |
| 7d R = n-octyl | 3 * 10⁻⁴ | 1.8 * 10⁻² |
| 7e R = n-decyl | 7 * 10⁻⁴ | 1.9 * 10⁻² |
| 7f R = n-dodecyl | 7 * 10⁻⁵ | |
| 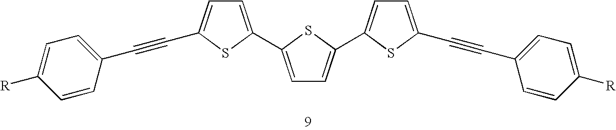 | | |
| R = n-C₄H₉ | 1.0 * 10⁻² | |
| R = n-C₆H₁₃ | 3.0 * 10⁻³ | |
| R = n-OC₆H₁₃ | 2.0 * 10⁻³ | |
| 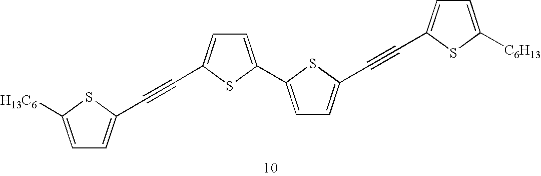 | 3.0 * 10⁻³ | |
| 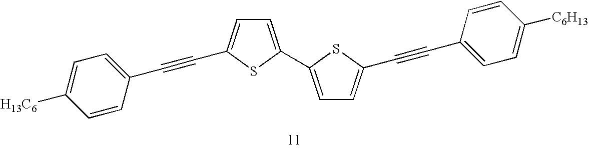 | 1.0 * 10⁻³ | |
| 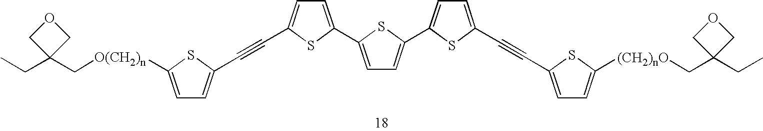 | | |
| N = 6 | 4 * 10⁻⁴ | |
| N = 8 | 2 * 10⁻⁴ | |
| 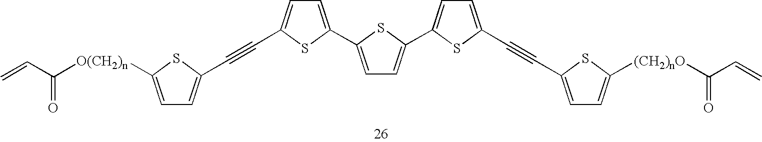 | | |
| N = 6 | 4 * 10⁻³ | |

### HMDS-Primed SiO₂ Bottom Gate Test Devices

Mobility with Top Gate Transistors.

Mobility experiments were repeated with transistors with a top gate geometry instead of a bottom gate geometry. On a glass substrate (W36), Ti/Au source and drain electrodes were fabricated in a thickness of about 50 nm using standard lithographic processing. A 25 nm thick polyimide layer (1051, JSP) was spincoated over the whole substrate. The film was prebaked at 90° C. for one hour followed by imidization at 180° C. for 3 hours. Then, the polyimide film was rubbed. Next, LC molecules were dissolved in toluene at 1 wt. % and spin coated at 1200 rpm. The device is then heated to 150° C. and slowly, about 5° C./min, cooled down to room temperature. As a gate dielectric a Teflon AF 1660 film of about 300 nm thick was used, which was spincoated from solvent FC75. The capacitance is about 6 nF/cm². Finally, a gold top gate electrode is evaporated through a shadow mask.

In a first experiment, use is made of 5,5″-bis(5-hexyl-2-thienylethynyl)-2,2′:5′,2″-terthiophenes. A monodomain is formed on cooling down to room temperature. It turned out that for this compound the formation of a monodomain strongly depends on the layer thickness. For film thicknesses larger than about 100 nm the multidomains are formed upon crystallization.

FIG. 4 shows the output characteristics of the transistor with the hexyl compound. The characteristics were measured in vacuum at 40° C. The channel length was 20 μm. At low gate bias, a clear non-ohmic contact resistance is observed. This might be due to the polyimide layer that is located in between the source drain contact and the LC semiconductor. Charge injection can only be through holes in the rubbed polyimide layer. In order to reduce the contact resistance, the source and drain electrodes can be fabricated on top of the polyimide layer.

FIG. 5 shows a graph of the linear and saturated mobility as a function of gate bias. The linear mobility is lower than the saturated one. This is probably due to the injection barrier as well. The saturated mobility is around 0.03 cm²/Vs. The mobility can be optimized by changing the type of gate dielectric. An increase of the mobility by a factor of about three is expected.

To benchmark the electrical transport data, multidomain top gate and bottom gate transistors of the hexyl compound were fabricated. The mobility in multidomain top gate transistors varied from 0.0001 to 0.003 cm²/Vs. With our standard HMDS-primed SiO₂ bottom gate test devices various transistors were made. The mobility is typically 2.10⁻³ cm²/Vs. This shows that the field-effect mobility improves by about one order of magnitude upon macroscopic alignment of the LC molecules in the transistor channel.

In a second experiment use is made of 5,5″-bis(5-decyl-2-thienylethynyl)-2,2′:5′,2″-terthiophenes. Similar values for the field-effect mobility, i.e. 0.03 cm²/Vs, in monodomain top gate transistors were found.

In a third experiment use is made of bisacrylates of the hexyl compound. Although the optimal processing conditions have not yet been found, a field-effect mobility of 5 10⁻³ cm²/V is realized. A photoinitiator was present in the composition spun onto the substrate. Subsequently, after bringing the material into a monodomain structure, it was cross-linked. Herein, the monodomain structure was maintained.

Summarizing, the electronic device comprises an organic semiconductor material in a monodomain structure on a substrate. It is preferably part of a transistor, wherein the monodomain extends on the channel, i.e. from a source to a drain electrode. The material comprises a mesogenic unit with spacer groups and end groups. The end groups are preferably reactive, i.e. dienes, acrylates, oxetanes or the like. The mesogenic unit contains a central oligothiophenyl group, rigid spacer groups, particularly acetylenes, and additional groups, for instance thiophenyl or phenyl.

1. An electronic device comprising a semiconductor element provided with an organic semiconductor material that comprises mesogenic units that are present in a smectic or crystalline phase and are at least partially ordered in a monodomain structure, said mesogenic units corresponding to the formula:
E¹-D¹-A¹-Z¹-A²-Z²-A³-D²-E², in which formula:
E¹, E² are end groups,
D¹, D² are spacer groups,
A¹, A², A³ are optionally substituted conjugated units,
Z¹, Z² are rigid spacer groups,
wherein A² is chosen from the group of oligothiophenyl groups.

2. An electronic device as claimed in claim 1, wherein at least part of the end groups are reactive end groups that are at least partially cross-linked into a polymer network.

3. An electronic device as claimed in claim 1, wherein a first and a second mesogenic unit are present, which are mutually different.

4. An electronic device as claimed in claim 3, wherein the first and second mesogenic unit differ in the length of the spacer groups D¹, D².

5. An electronic device as claimed in claim 1, wherein the semiconductor element is a thin-film transistor provided with a source electrode and a drain electrode that are mutually separated by a channel containing the organic semiconductor material, which transistor is further provided with a gate electrode that is separated from the channel by a gate dielectric, in which transistor an alignment layer is present that is separate from an interface between the gate dielectric and the channel, and wherein the transistor has a top gate structure, in which the channel is present between the gate dielectric and the alignment layer.

6. An electronic device as claimed in claim 5, wherein the channel has a thickness of at most 200 nm.

7. A method of manufacturing an electronic device as claimed in claim 1, comprising the steps of:
providing a substrate,
applying a layer of an organic semiconductor material on the substrate, said organic semiconductor material comprising mesogenic units corresponding to the formula:
E¹-D¹-A¹-Z¹-A²-Z²-A³-D²-E², in which formula:
E¹, E² are end groups,
D¹, D² are spacer groups,
A¹, A², A³ are optionally substituted conjugated units,
Z¹, Z² are rigid spacer groups,
wherein A² is chosen from the group of oligothiophenyl groups, and
applying a heat treatment followed by cooling, thereby orienting the mesogenic units, in accordance with alignment means, into a smectic or optionally a crystalline phase, in which a structure is formed comprising at least one monodomain structure.

8. A method as claimed in claim 7, wherein at least part of the end groups is a reactive end group, and wherein the method comprises the additional step of cross-linking said reactive end groups after forming the monodomain structure.

9. A method as claimed in claim 8, wherein the reaction is initiated upon irradiation, said irradiation being performed in a patterned manner, and wherein non-exposed areas of the organic semiconductor layer are subsequently removed by exposure to a suitable solvent.

10. A method as claimed in claim 7, comprising the additional steps of:
providing source and drain electrodes in advance of applying the semiconductor material,
applying an at least partially organic dielectric and a gate electrode on the dielectric, such that the gate electrode overlies a portion of the semiconductor layer that is present between the source and the drain electrode.

11. A reactive mesogenic compound corresponding to the formula:
E¹-D¹-A¹-Z¹-A²-Z²-A³-D²-E²,
in which formula:
E¹, E² are end groups, of which E¹ includes at least one reactive end group that is cross-linkable upon initiation;
D¹, D² are spacer groups,
A¹, A², A³ are optionally substituted conjugated units,
Z¹, Z² are rigid spacer groups,
wherein A² is chosen from the group of oligothiophenyl groups.

12. A compound as claimed in claim 11, wherein the number of thiophene rings in A₂ is between 1 and 6, preferably 2 or 3.

13. A compound as claimed in claim 11, wherein the groups A¹ and A³ are equal and chosen from the group of optionally substituted thiophenyl and phenyl groups.

14. A compound as claimed in claim 11, wherein Z¹, Z² are acetylene groups.

15. A compound as claimed in claim 11, wherein the reactive mesogenic unit is symmetric to the extent that A¹ and A³ are equal to each other, D¹ and D² are equal to each other and E¹ and E² are equal to each other.

16. A polymer network comprising reactive mesogenic units as claimed in claim 11, of which at least reactive end groups E¹ have been cross-linked

17. The use of the materials as claimed in claim 11 in an electronic component.

18. A semi-manufactured article comprising a substrate with an alignment layer and a layer of an organic semiconductor material comprising reactive mesogenic units as claimed in claim 11,
wherein said mesogenic units have been oriented in accordance with the alignment layer into a smectic or a crystalline phase and have been ordered into at least one monodomain structure.

19. A composition comprising, in a solvent, a first mesogenic unit as claimed in claim 11 and a second mesogenic unit provided with at least one reactive end group, which first and second mesogenic unit are mutually different and, upon cross-linking, have the same smectic or crystalline phase.

20. A composition as claimed in claim 19, wherein the first and the second mesogenic unit are different in the length of at least one of the spacer groups D¹, D².

21. A composition comprising, in a solvent, a first and a second mesogenic unit of the formula E¹-D¹-T-D²-E², in which formula:
E¹, E² are end groups, of which at least E¹ is cross-linkable upon initiation;
D¹, D² are spacer groups, and
T is a core comprising one or more, optionally substituted conjugated units, which first and second mesogenic unit are mutually different and, upon cross-linking, have the same smectic or crystalline phase.

22. An electronic device comprising a semiconductor element provided with an organic semiconductor material that comprises reactive mesogenic units that are present in a smectic or crystalline phase and are at least partially ordered in a monodomain structure, said mesogenic units corresponding to the formula:
E¹-D¹-T-D²-E²,
in which formula:
E¹, E² are end groups of which at least El is cross-linkable upon initiation,
D¹, D² are spacer groups,
T is a core comprising one or more, optionally substituted conjugated units,
wherein the material comprises a first and a second mesogenic unit that are mutually difference and, upon cross-linking, have the same smectic or crystalline phase.
